(19) United States
(12) Patent Application Publication
(10) Pub. No.: US 2011/0108854 A1
(43) Pub. Date: May 12, 2011

(54) SUBSTANTIALLY LATTICE MATCHED SEMICONDUCTOR MATERIALS AND ASSOCIATED METHODS

(76) Inventor: Chien-Min Sung, Tansui (TW)

(21) Appl. No.: 12/899,786

(22) Filed: Oct. 7, 2010

Related U.S. Application Data
(60) Provisional application No. 61/259,948, filed on Nov. 10, 2009.

(51) Int. Cl. H01L 29/66; H01L 21/18

(52) U.S. Cl. 257/77; 438/455; 257/190; 257/E29.166; 257/E21.087

(57) ABSTRACT

Semiconductor devices having atomic lattice matching template interlayers are provided. In one aspect, a semiconductor device can include a first semiconductor material, a second semiconductor material disposed on the first semiconductor material, and an atomic template interlayer disposed between the first semiconductor material and the second semiconductor material, the atomic template interlayer bonding together and facilitating a substantial lattice matching between the first semiconductor material and the second semiconductor material.

### PRIORITY DATA

This application claims the benefit of U.S. Provisional Patent Application Ser. No. 61/259,948, filed on Nov. 10, 2009, which incorporated herein by reference.

### FIELD OF THE INVENTION

The present invention relates generally to semiconductor materials and associated methods. Accordingly, the present invention involves the chemical and material science fields.

### BACKGROUND OF THE INVENTION

As computers and other electronic devices become smaller and faster, the demands placed on semiconductor devices utilized therein increase geometrically. Ultra-large-scale integration (ULSI) is a technology that places at least 1 million circuit elements on a single semiconductor chip. In addition to the tremendous density issues that already exist, with the current movement toward size reduction, ULSI is becoming even more delicate, both in size and materials than ever before. As current technology moves beyond ULSI, several barriers emerge that may be insurmountable with current wafer and substrate materials.

One barrier arises due to the accumulation of heat that may not be effectively channeled out of the crystal lattice of many semiconductor materials. Semiconductors tend to have thermal conductivities that are a fraction of copper metal. Hence, semiconductor devices are often cooled with copper heat spreaders. However, as the power requirements future generations of semiconductor devices increase, copper heat spreaders will become reservoirs for heat accumulation.

Another barrier arises due to the accumulation of charge carriers, i.e. electrons and holes, which are intrinsic to quantum fluctuation. Accumulation of the carriers creates noise, and tends to obscure electrical signals within the semiconductor device. This problem is compounded as the temperature of the device increases. Much of the carrier accumulation may be due to the intrinsically low bonding energy and the directional anisotropy of typical semiconductor crystal lattices.

Yet another barrier may be a further result of current semiconductor materials. These semiconductors tend to have a high leaking current and a low break down voltage. As the size of semiconductor transistors and other circuit elements decrease, coupled with the growing need to increase power and frequency, current leak and break down voltage also become critical.

An inherent crystal lattice mismatch is present between semiconductor materials due to the difference in atomic size. Crystal lattice mismatch between semiconductor materials tends to exacerbate these problems. For semiconductor deposition techniques, grading of materials between semiconductor layers has been attempted to alleviate this size disparity. A less costly method for the manufacture of semiconductor devices is the wafer bonding of semiconductor materials together. In such materials, however, large lattice mismatches are inevitable. While intermediate semiconductor layers such as sapphire can be used to reduce the lattice mismatches, they cannot generally be eliminated.

### SUMMARY OF THE INVENTION

Accordingly, the present invention provides semiconductor devices having atomic lattice matching template interlayers, including associated methods. In one aspect, for example, a semiconductor device can include a first semiconductor material, a second semiconductor material disposed on the first semiconductor material, and an atomic template interlayer disposed between the first semiconductor material and the second semiconductor material, the atomic template interlayer bonding together and facilitating a substantial lattice matching between the first semiconductor material and the second semiconductor material.

A variety of materials can be utilized for the atomic template interlayer, and any material capable of facilitating substantial lattice matching between a first and second semiconductor layer is considered to be within the present scope. Non-limiting examples of atomic template interlayer materials can include graphene, planar hexagonal boron nitride, planar hexagonal silicon carbide, and the like, including combinations thereof. In one specific example, the atomic template interlayer material can include graphene. Additionally, the atomic template interlayer can be used in thicknesses having varying numbers of layers. In one aspect, for example, the atomic template interlayer can be less than or equal to five atom layers thick. In another aspect, the atomic template interlayer can be greater than five atom layers thick.

In one aspect of the present invention, the first semiconductor material can be a diamond material, and the atomic template interlayer can be graphene. A variety of methods can be utilized for disposing a graphene layer on the diamond semiconductor material. In one specific aspect, the atomic template interlayer can be a graphenized surface of the diamond material. In yet another specific aspect, the second semiconductor material can be GaN. The resulting diamond/GaN semiconductor device can be utilized for a variety of applications, including, without limitation, an LED device.

The present invention additionally provides methods of making a semiconductor device. Such a method can include applying an atomic template interlayer to a first semiconductor material, and applying a second semiconductor material to the atomic template interlayer such that the atomic template interlayer is disposed between the first semiconductor material and the second semiconductor material. The first semiconductor material and the second semiconductor material can then be bonded together such that the atomic template interlayer facilitates a substantial lattice-matching between the first semiconductor material and the second semiconductor material.

There has thus been outlined, rather broadly, various features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### BRIEF DESCRIPTION OF THE DRAWINGS

FIG. 1 is a cross-sectional view of a semiconductor device in accordance with one embodiment of the present invention.

FIG. 2 is a graphical representation of a graphene lattice in accordance with another embodiment of the present invention.

### DETAILED DESCRIPTION OF THE INVENTION

### Definitions

In describing and claiming the present invention, the following terminology will be used in accordance with the definitions set forth below.

The singular forms “a,” “an,” and, “the” include plural referents unless the context clearly dictates otherwise. Thus, for example, reference to “a particle” includes reference to one or more of such particles, and reference to “the material” includes reference to one or more of such materials.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually. This same principle applies to ranges reciting only one numerical value as a minimum or a maximum. Furthermore, such an interpretation should apply regardless of the breadth of the range or the characteristics being described.

### THE INVENTION

The present invention relates to novel semiconductor devices having at least two semiconductor layers that are at least substantially lattice matched. Such lattice matching can be achieved using an atomic template interlayer to bridge the atomic misalignment between semiconductor layers. In one aspect, the atomic template interlayer can be an atomically planar multilayer material such as, for example, graphene, hexagonal boron nitride, hexagonal silicon carbide, and the like. It should be noted that, for convenience sake, graphene will be discussed frequently herein. This discussion should not be seen as limiting however, and, unless the context dictates otherwise, such discussion should be seen as applicable to other atomically planar materials.

Lattice matching between semiconductor layers, whether wafer bonded or grown on one another, can prove difficult for most semiconductor materials. For example, silicon wafers are widely available for use in constructing semiconductor devices, but these wafers are difficult to grow GaN upon epitaxially because the nitrogen atoms of the GaN are small as compared to silicon atoms. Consequently, sapphire wafers (Al₂O₃) are commonly used in an attempt to reduce the atomic size disparity between nitrogen and silicon atoms. Even using this intermediate material, the size disparity and thus the lattice mismatch between GaN and Al₂O₃ is large, about 15%. This lattice mismatch introduces numerous crystal dislocations and disparities into the GaN layer on the order of about one billion per square centimeter in some cases.

Graphene is essentially a stretched plane of diamond's (111) face, having an sp² bonding arrangement capable of forming sigma and pi bonds. In this form, graphene can align and thus match with nearly every other atom of many common semiconductor materials, such as Si, N, and the like. If allowed to pucker to form sp³ bonds, a graphene layer can lattice match with many semiconductor materials with even greater correspondence due to the alteration in interatomic distances as compared to sp² bonding. For graphene materials having multiple layers, atomic puckering at the semiconductor/graphene interface on both sides of the graphene allows a substantially lattice matched transition to occur between the semiconductor layers. Thus, graphene can act as a bridge between the semiconductor materials while at the same time maintaining a tight packing of atoms that is conducive to many semiconductive processes.

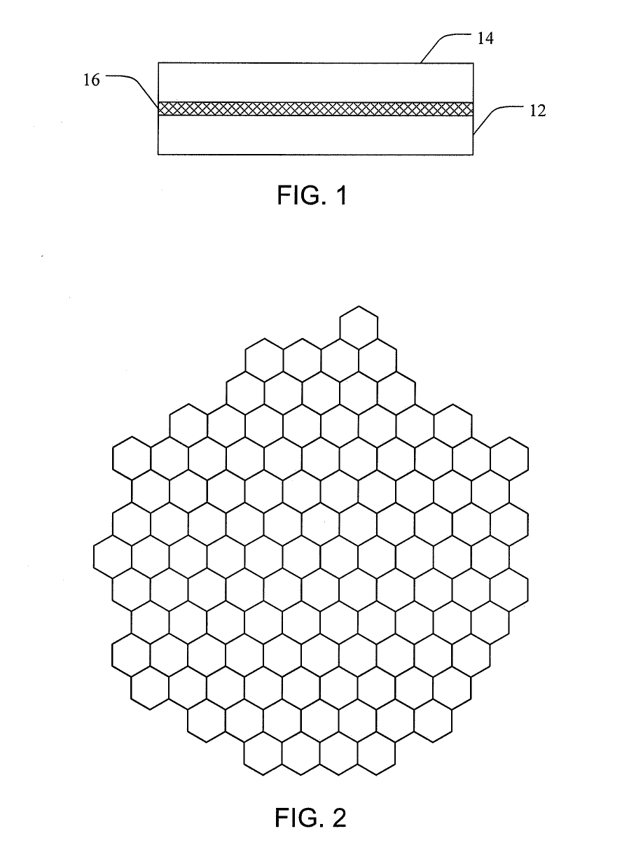

Accordingly, in one aspect of the present invention, as is shown in FIG. 1, a semiconductor device is provided. Such a device can include a first semiconductor material 12, a second semiconductor material 14 disposed on the first semiconductor material 12, and an atomic template interlayer 16 disposed between the first semiconductor material 12 and the second semiconductor material 14. In this case, the atomic template interlayer bonds together and facilitates a substantial lattice-matching between the first semiconductor material and the second semiconductor material.

Various materials are contemplated for use as an atomic template interlayer. Any planar sp² bonded material capable of facilitating lattice matching between semiconductor layers should be seen to be within the present scope. In one aspect, non-limiting examples of atomic template interlayer materials can include graphene, planar hexagonal boron nitride, planar hexagonal silicon carbide, and combinations thereof. In one specific aspect, the atomic template interlayer is graphene.

As shown in FIG. 2, graphene is a one-atom-thick planar sheet of sp2-bonded carbon atoms that are densely packed into a benzene-ring structure in a honeycomb crystal lattice. For purposes of the present invention, the term graphene is considered to include single layers of graphene and multiple layers of graphene. The carbon-carbon bond length in graphene is approximately 1.45 Å, which is shorter than that of diamond at 1.54 Å. Graphene is the basic structural element of other graphitic materials including graphite, carbon nanotubes, fullerenes, etc. It should be noted that the term “graphene” according to aspects of the present invention includes reference to both single atom layers of graphene and multiple layer stacks of graphene.

Perfect graphene planes consist exclusively of hexagonal cells, and any pentagonal or heptagonal cells within a graphene plane would constitute defects. Such defects alter the planar nature of the graphene layer. For example, a single pentagonal cell warps the plane into a cone shape, while 12 pentagons at the proper locations would create a fullerene of the plane. Also, a single heptagon warps the plane into a saddle-shape. Warpage of the graphene plane tends to reduce electron mobility and thermal conductivity, and thus may be undesirable for applications where these properties are valued.

The atomic template interlayer materials according to aspects of the present invention can be manufactured according to a variety of methods, and any method of manufacturing these materials is within the present scope. One method of producing such materials includes formation on a molten solvent layer. Details concerning such manufacturing methods can be found in Applicant's pending U.S. patent application Ser. No. 12/499,647, filed on Jul. 8, 2009, which is incorporated herein by reference. Other methods include solid state diffusion, vapor deposition, exfoliation, exsolution, and the like.

The atomic template interlayer can include various numbers of planar layers. In one aspect, for example, the atomic template interlayer can be a single atom layer thick. In another aspect, the atomic template interlayer can be less than or equal to five atom layers thick. In yet another aspect, the atomic template interlayer can be greater than five atom layers thick. In other aspects, the atomic template interlayer can be greater than 10, 100, 1000, or even 10,000 atom layers thick. The thickness of the atomic template layer can depend on the manufacturing method of the material. These materials are often made in stacks having many layers, and these layers are separated into single or multiple layer materials. Thus the methods used to separate these layer materials can, to some extent, dictate the number of layers in the atomic template interlayer. As has been described, in some aspects it can be desirable to utilize an atomic template interlayer having multiple planar layers to allow puckering to occur more readily on both sides of the atomic template layer, thus further facilitating substantial lattice matching between semiconductor materials. In such cases, the interlayer materials will exhibit a gradient of puckering, with the greatest distortion of the interlayer occurring at the interface with the semiconductor material, with less distortion occurring in interlayers that are further away from this interface.

In some aspects of the present invention, the atomic template interlayer can be manipulated in order to improve the puckering of the material, and thus facilitate greater lattice matching between semiconductor materials. In one aspect, for example, the atomic template interlayer can be stretched, compressed, or twisted to facilitate the substantial lattice-matching between the first semiconductor material and the second semiconductor material. In another aspect, the flexibility of the atomic template interlayer can be altered by associating intercalating atoms therewith. As a non-limiting example, graphene and hBN layers can be doped with Si to alter the flexibility of those materials.

In some aspects of the present invention, atomic template interlayer materials can be doped with a variety of dopants. Dopants can be utilized to alter the physical properties of an interlayer material, and/or they can be utilized to alter the physical interactions between interlayers within a stack. For example, in one aspect, doping can affect the flexibility of the interlayer material as has been described above. In another aspect, an interlayer material can be doped to alter the electrical properties of the material. Additionally, doping interlayer materials can also alter the electrical properties of the interlayers with respect to one another. Such doping can occur by adding a dopant during formation of the interlayer material, or it can occur following such formation by depositing the dopant into the interlayer. It should be noted that interlayer materials that are undoped can exhibit dielectric properties, and thus be utilized as the intermediate layer in p-i-n junctions.

Various dopants are generally known, and any useful dopants should be considered to be within the present scope. In one aspect, for example, graphene can be doped with boron to form a P-type semiconductor. A variety of dopants can be utilized for doping the graphene layers, with specific non-limiting examples including boron, phosphorous, nitrogen, and combinations thereof. Doping can also be utilized to alter the electron mobility of specific regions of the interlayer for the formation of circuits within the semiconductor device. Such site specific doping can allow the patterning of electrical circuits within the interlayer portion of the device. Furthermore, graphene layers, for example, have a high electron mobility. Conductivity between graphene layers in a stack, however, is more limited. By doping with metal atoms or other conductive materials, the electron mobility between stacked layers can be increased.

In some aspects of the present invention, hexagonal boron nitride layers can be doped with a variety of dopants. Dopants can be utilized to alter the physical properties of a hexagonal boron nitride layer, and/or they can be utilized to alter the physical interactions between hexagonal boron nitride layers within a stack. Such doping can occur by adding a dopant during formation of the hexagonal boron nitride layer, or it can occur following the formation of the hexagonal boron nitride layer by depositing the dopant in the layer. A variety of dopants can be utilized for doping the hexagonal boron nitride layers. Specific non-limiting examples can include silicon, Mg, and combinations thereof. Doping the hexagonal boron nitride with silicon results in an N-type semiconductor material.

Diamond is an excellent material to use as a semiconductor substrate due to the high atomic density and high thermal conductivity of this material. The accumulation of charge carriers in a semiconductor device creates noise, and thus tends to obscure electrical signals within the device. This problem is compounded as the temperature of the device increases. Much of the carrier accumulation may be due to the intrinsically low bonding energy and the directional anisotropy of typical semiconductor crystal lattices. Another problem may be a further result of current semiconductor materials. These semiconductors tend to have a high leaking current and a low break down voltage. As the size of semiconductor transistors and other circuit elements decrease, coupled with the growing need to increase power and frequency, current leak and break down voltage also become critical. Diamond materials can be used to reduce many of these problems. The physical properties of diamond, such as its high thermal conductivity, low intrinsic carrier concentration, and high band gap, make it a desirable material for use in many semiconductor devices.

As such, the first semiconductor material in a semiconductor device can be a layer of diamond. As such, a second semiconductor material can be bonded to the diamond material with an atomic template interlayer sandwiched therebetween. In one aspect, for example, the atomic template interlayer can be a graphene material disposed between the diamond and the second semiconductor material. In another aspect, a surface of the diamond layer can be graphenized, thus forming a graphene layer thereupon. The second semiconductor material can subsequently be bonded to the graphenized surface of the diamond to form a semiconductor device that is substantially lattice matched. Various methods can be used to graphenize a layer of graphene on a diamond surface, and any method capable of doing such should be considered to be within the present scope. In one example, the diamond surface can be heat treated in a vacuum to form the graphene layer. In another example, a catalytic metal can applied to a diamond surface under heat to catalyze the production of a graphene layer thereon. Examples of catalytic metals can include, without limitation, Fe, Co, Ni, and combinations and alloys thereof.

The tight correspondence between diamond and graphene, particularly in those cases where the graphene was formed on the diamond surface, allow these materials to be used in the construction of high quality semiconductor devices. As one example, such material can be used in the manufacture of high power LED devices. For example, a diamond layer having a graphene surface can be bonded to a GaN semiconductor layer to form a high quality LED. Substantial lattice matching results in very low if any crystal dislocations, and as such, LEDs made therefrom can have high brightness at sustained high power output due to the thermal dissipation properties of the diamond material.

In another aspect of the present invention, a method of making a semiconductor device is provided. Such a method can include applying an atomic template interlayer to a first semiconductor material, and applying a second semiconductor material to the atomic template interlayer, such that the atomic template interlayer is disposed between the first semiconductor material and the second semiconductor material. The method can further include bonding the first semiconductor material to the second semiconductor material such that the atomic template interlayer facilitates a substantial lattice-matching between the first semiconductor material and the second semiconductor material.

Various methods are possible for bonding the semiconductor materials together with the atomic template interlayer. Generally, any method capable of chemically bonding the atomic template interlayer to a semiconductor material should be considered to be within the present scope. In one aspect, for example, the semiconductor materials and the interlayer can be pressed together under heat and pressure sufficient to cause bonding to occur. Typical temperatures can range from about 200° C. to about 800° C., and typical pressure can range from about 10 MPa to about 50 MPa. It should be noted that wafer bonding can be accomplished using supersmooth surfaces that have been cleaned of foreign atoms that may interfere with the bonding process. Such bonding can be achieved in a vacuum, where heat is applied to facilitate the vibration of atoms and a slight interdiffusion of atoms between the joining lattices.

### EXAMPLE

### Example 1

Diamond is sputtered with a thin layer of Ni and heated to 600° C. Ni atoms associate with roughly every other carbon atom, and function to flatten diamond surface atoms. In particular, a graphene-like (111) face is produced. The Ni is etched from the graphene surface to form a graphene coated diamond material.

### Example 2

A blue light LED made of doped GaN grown from sapphire with an interlayer of amorphous AlN is bonded to a temporary transfer plate. The sapphire is split and removed from the LED by laser irradiation of the amorphous layer to cause thermal expansion stress. The split LED is CMP polished and cleaned on the now smooth surface. The smooth surface of the LED is pressed against the graphene-like surface of the diamond material of Example 1 using a weight. The assembly is placed in a vacuum furnace and heated to 600° C. to wafer bond the graphene to the GaN lattice. The resulting LED has greatly improved thermal conductivity.

### Example 3

A polished Si wafer is implanted with hydrogen atoms to a depth of about 1 micron. The hydrogen implanted Si wafer is wafer bonded to a 10 micron thick polished diamond film using multiple graphene layers between the Si wafer and the diamond. Wafer bonding is achieved by vacuum compression at 600° C. Heat or microwave is applied to split the Si wafer at the 1 micron deep layer of hydrogen atoms to create a thin layer of Si on diamond. The Si layer can then be polished to create a smooth working surface. The resulting silicon on diamond material has a high thermal conductivity and is useful for many semiconductor devices.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A semiconductor device, comprising:
a first semiconductor material;
a second semiconductor material disposed on the first semiconductor material; and
an atomic template interlayer disposed between the first semiconductor material and the second semiconductor material, the atomic template interlayer bonding together and facilitating a substantial lattice-matching between the first semiconductor material and the second semiconductor material.

2. The semiconductor device of claim 1, wherein the atomic template interlayer includes a member selected from the group consisting of graphene, planar hexagonal boron nitride, planar hexagonal silicon carbide, and combinations thereof.

3. The semiconductor device of claim 2, wherein the atomic template interlayer is graphene.

4. The semiconductor device of claim 1, wherein the atomic template interlayer is less than or equal to five atom layers thick.

5. The semiconductor device of claim 1, wherein the atomic template interlayer is greater than five atom layers thick.

6. The semiconductor device of claim 1, wherein the first semiconductor material is a diamond material, and the atomic template interlayer is graphene.

7. The semiconductor device of claim 6, wherein the atomic template interlayer is a graphenized surface of the diamond material.

8. The semiconductor device of claim 7, wherein the second semiconductor material is GaN.

9. The semiconductor device of claim 1, wherein the atomic template interlayer is stretched, compressed, or twisted to facilitate the substantial lattice-matching between the first semiconductor material and the second semiconductor material.

10. The semiconductor device of claim 1, wherein the atomic template interlayer is doped with a dopant.

11. The semiconductor device of claim 10, further including intercalating atoms associated with the atomic template interlayer operable to alter flexibility of the atomic template interlayer.

12. A method of making a semiconductor device, comprising:
applying an atomic template interlayer to a first semiconductor material;
applying a second semiconductor material to the atomic template interlayer, such that the atomic template interlayer is disposed between the first semiconductor material and the second semiconductor material; and
bonding the first semiconductor material to the second semiconductor material, such that the atomic template interlayer facilitates a substantial lattice-matching between the first semiconductor material and the second semiconductor material.

13. The method of claim 12, wherein the atomic template interlayer includes a member selected from the group consisting of graphene, planar hexagonal boron nitride, planar hexagonal silicon carbide, and combinations thereof.

14. The method of claim 12, wherein the atomic template interlayer is graphene.

15. The method of claim 12, wherein the first semiconductor material is a diamond material, and further comprising graphenizing a surface of the diamond material to form an atomic template interlayer of graphene.

16. The method of claim 12, further including associating intercalating atoms with the atomic template interlayer to alter flexibility of the atomic template interlayer.

17. The method of claim 12, wherein bonding the first semiconductor material to the second semiconductor material includes heating the first semiconductor material, the second semiconductor material, and the atomic template interlayer to a temperature under pressure to facilitate chemical bonding between the first semiconductor material, the second semiconductor material, and the atomic interlayer.

18. The method of claim 17, wherein the pressure is from about 1° MPa to about 50 MPa.

19. The method of claim 17, wherein the temperature is from about 200° C. to about 800° C.

20. The method of claim 12, further comprising stretching, compressing, or twisting the atomic template interlayer to facilitate the substantial lattice-matching between the first semiconductor material and the second semiconductor material.
